(19) United States
(12) Patent Application Publication
(10) Pub. No.: US 2013/0211759 A1
(43) Pub. Date: Aug. 15, 2013

(54) METHOD FOR EVALUATING THE EFFECTS OF AN INTERCONNECTION ON ELECTRICAL VARIABLES

(71) Applicants: TEKCEM, (US); Frédéric BROYDE, (US); Evelyne CLAVELIER, (US)

(72) Inventors: Frédéric BROYDE, Maule (FR); Evelyne CLAVELIER, Maule (FR)

(73) Assignee: TEKCEM, Maule (FR)

(21) Appl. No.: 13/849,966

(22) Filed: Mar. 25, 2013

Related U.S. Application Data
(63) Continuation of application No. PCT/IB2012/052705, filed on May 30, 2012.

(30) Foreign Application Priority Data
Jun. 7, 2011 (FR) 1101720

(51) Int. Cl. G01R 27/28

(52) U.S. Cl. CPC G01R 27/28
USPC 702/79

(57) ABSTRACT

The invention relates to a method for evaluating the effects of a multiconductor interconnection on electrical variables in an electronic circuit or system, which takes into account the frequency dependent couplings between the conductors to obtain an accurate evaluation of effects such as propagation delay, attenuation, linear distortions, echo and crosstalk.

The method comprises the steps of: identifying segments having suitable properties; defining, for each segment, a per-unit-length external impedance matrix of the segment and a per-unit-length internal impedance matrix of the segment; defining, for each segment, a model of the per-unit-length internal impedance matrix of the segment; and simulating the circuit using, for each segment, a multiconductor transmission line model and the model of the per-unit-length internal impedance matrix of the segment defined at the previous step.

### CROSS REFERENCE TO RELATED APPLICATIONS

This is a Continuation Application of PCT application PCT/IB2012/052705, filed 30 May 2012, published in English under No. WO 2012/168833, which in turn claims priority to French patent application No. 11/01720 of 7 Jun. 2011, entitled “Procédé pour évaluer les effets d'une interconnexion sur des variables électriques”, both of which are incorporated herein by reference.

### FIELD OF THE INVENTION

The invention relates to a method for evaluating the effects of a multiconductor interconnection on electrical variables in an electronic circuit or system, which takes into account the frequency dependent couplings between the conductors to obtain an accurate evaluation of effects such as propagation delay, attenuation, linear distortions, echo and crosstalk. The invention also relates to a computer program product implementing this method.

### PRIOR ART

Continued progress in the design of electronic circuits and systems requires the accurate evaluation of the effects of critical multiconductor interconnections on the electrical variables in a circuit, during the simulation of electronic circuits or systems. Here, “critical multiconductor interconnections” mainly refers to relatively long electrical multiconductor interconnections used to send high-frequency or wide-band analog signals, or fast digital signals. Here, “electrical variables” refers to voltages, currents of other electrical variables. Such a simulation must accurately predict propagation delays, attenuation, linear distortions caused by the variations of attenuation and propagation velocity with frequency (dispersion), couplings between conductors (which may produce crosstalk) and reflections (which may produce echo and/or crosstalk). Such a simulation requires a suitable model for multiconductor interconnections.

The article of P. Triverio, S. Grivet-Talocia, M. S. Nakhla, F. G. Canavero and R. Achar entitled “Stability, causality and passivity in electrical interconnect models”, published in the journal IEEE Transactions on Advanced Packaging, vol. 30, No. 7, in November 2007, explains that it is very important to use a multiconductor interconnection model for which the fundamental property of passivity is guaranteed.

At the present time, there are three main approaches for evaluating the effects of an electrically long multiconductor interconnection having n transmission conductors, on the electrical variables in a circuit, where n is an integer greater than or equal to two.

The first approach for evaluating the effects of a multiconductor interconnection having n transmission conductors is based on the assumption that the multiconductor interconnection can be modeled as a multiconductor transmission line. It is important to clearly distinguish the multiconductor interconnection, a physical device composed of conductors and dielectrics, from the well-known multiconductor transmission line model. In order to obtain an accurate simulation of an electronic circuit or system comprising a multiconductor transmission line model, it is in most cases necessary to take into account the fact that the resistive losses occurring in the conductors depend on frequency. As explained in the section 5.3 of the book Analysis of Multiconductor Transmission Lines, of C. R. Paul, published by John Wiley & Sons in 1994, this can be achieved by introducing the per-unit-length internal impedance matrix, a frequency dependent complex n×n matrix denoted by Z_{I} and such that the per-unit-length impedance matrix, a frequency dependent complex n×n matrix denoted by Z, is given by

Z=Z_{I}+jωL₀

where ω is the radian frequency, where j²=−1 and where L₀ is the per-unit-length inductance matrix computed at a non-zero frequency under the assumption that all conductors of the interconnection are ideal conductors, that is to say lossless conductors. Equivalently, L₀ is the per-unit-length inductance matrix computed using the high-frequency current distribution in the conductors, this high-frequency current distribution being such that the skin effect and the proximity effect are fully developed. L₀ is a frequency independent real n×n matrix sometimes referred to as the “per-unit-length external inductance matrix”, or more precisely as the “high-frequency per-unit-length external inductance matrix”. The matrix jωL₀ is the per-unit-length external impedance matrix. Since Z_{I} is caused by the losses in the conductors, we can say that Z_{I}=0 for lossless conductors, so that jωL₀ is the per-unit-length impedance matrix computed as if all conductors of the interconnection were ideal conductors.

A precise computation of Z_{I} is very involved and time-consuming. Consequently, a circuit simulation comprising a multiconductor transmission line model taking into account frequency dependent resistive losses typically assumes that Z_{I} is equal to the model Z_{S} given by

$${Z}_{S} = {R}_{DC} + \frac{1 + j}{\sqrt{2}} \sqrt{ω} B$$

where R_{DC} is the per-unit-length resistance matrix at the frequency of 0 Hz, and where B is a frequency-independent real n×n matrix. The model Z_{S} has a correct behavior at high frequencies and it can be shown that it represents a passive linear system if B is positive definite. Unfortunately, Z_{S} is a poor approximation of Z_{I} in a wide frequency range (four decades of frequency) where neither the term R_{DC} nor the term containing B is negligible in Z_{S}. Consequently, this approach often provides poor simulation results.

The second approach for evaluating the effects of a multiconductor interconnection having n transmission conductors is based on a model consisting of a cascade of lumped-element sections, each section being a network of resistors, inductors, capacitors and mutual inductance couplings, referred to as RLC network. This approach is for instance used in the patent of the States of America U.S. Pat. No. 6,342,823 entitled “System and method for reducing calculation complexity of lossy, frequency-dependent transmission-line computation” and in the patent of the United States of America U.S. Pat. No. 6,418,401 entitled “Efficient method for modeling three-dimensional interconnect structures for frequency-dependent crosstalk simulation”. This approach has the advantage of using an obviously linear and passive model. Unfortunately, this approach is ineffective or inaccurate for long multiconductor interconnections used for high-speed signal transmission, because:
an RLC network providing a sufficient accuracy of Z_{I} up to the highest frequencies needed for the simulation must contain many circuit elements;
the number of circuit elements needed in each section increases rapidly when n is increased;
an accurate simulation of an electrically long interconnection requires a large number of sections.

The third approach for evaluating the effects of a multiconductor interconnection having n transmission conductors is based on the use of data tabulated as a function of frequency, to obtain a model using delayed rational functions, referred to as a delayed rational macromodel. The article of A. Chinea, S. Grivet-Talocia and P. Triverio entitled “On the performance of weighting schemes for passivity enforcement of delayed rational macromodels of long interconnects” and the article of A. Charest, M. Nakhla and R. Achar entitled “Passivity verification and enforcement of delayed rational approximations from scattering parameter based tabulated data”, both published in the Proceedings of the IEEE 18th Topical Meeting on Electrical Performance of Electronic Packaging and Systems, EPEPS 2009, in October 2009, explain this approach and show that it is difficult to obtain a model such that the fundamental property of passivity is guaranteed. Additionally, whenever the length of the interconnection is changed, a new delayed rational macromodel must be computed.

At the early design stage of an integrated circuit, multi-chip module or printed circuit assembly, it is important to be able to use the length of an interconnection as a parameter of an accurate simulation. A change in the length of the interconnection must not require a long computation time to obtain new simulation results. Regarding this requirement, the first approach, based on the multiconductor transmission line model, has the best performance. Unfortunately, as explained above, this approach often does not provide accurate simulation results for lack of a suitable model for the per-unit-length internal impedance matrix Z_{I}.

### SUMMARY OF THE INVENTION

The purpose of the invention is an accurate evaluation of the effects of a multiconductor interconnection on one or more electrical variables in an electronic circuit or system, which takes into account the effects of the frequency dependent resistive losses occurring in the conductors and avoids the above-mentioned drawbacks of prior art methods.

The method of the invention is a method for evaluating, in a known frequency band, the effects of a multiconductor interconnection on one or more electrical variables in a circuit, the multiconductor interconnection being a part of the circuit, the multiconductor interconnection having n transmission conductors, where n is an integer greater than or equal to two, the method comprising the steps of:
identifying a segment of the multiconductor interconnection, the segment being such that, over the segment, the multiconductor interconnection may be modeled, in the known frequency band, as a multiconductor transmission line having a per-unit-length impedance matrix, said per-unit-length impedance matrix being referred to as the total per-unit-length impedance matrix of the segment;
defining a per-unit-length external impedance matrix of the segment as the per-unit-length impedance matrix of the segment if all conductors of the segment were ideal conductors, and a per-unit-length internal impedance matrix of the segment as the total per-unit-length impedance matrix of the segment minus the per-unit-length external impedance matrix of the segment, the per-unit-length internal impedance matrix of the segment being a non-diagonal matrix in a part of the known frequency band;
defining a model of the per-unit-length internal impedance matrix of the segment, the model of the per-unit-length internal impedance matrix of the segment being a complex n×n matrix such that a non-diagonal entry of the model of the per-unit-length internal impedance matrix of the segment is given by a function of frequency, of one or more frequency independent quantities representative of the resistive losses in the conductors of the segment at frequencies for which the skin effect is fully developed, and of one or more frequency independent quantities representative of the resistive losses in the conductors of the segment at frequencies for which the skin effect is negligible, the function being defined at any nonnegative frequency, the limit, as the frequency becomes arbitrarily large, of the ratio of the function to an exponentiation involving frequency existing and being a nonzero complex number, the exponentiation involving frequency being equal to frequency raised to a power, said power being greater than or equal to 1/4 and less than or equal to 4/5, the function being differentiable with respect to frequency at any nonnegative frequency and the partial derivative of the function with respect to frequency at the frequency of zero Hertz being a number having an imaginary part greater than the absolute value of its real part;
simulating the circuit using, in the known frequency band, for the segment, a multiconductor transmission line model and the model of the per-unit-length internal impedance matrix of the segment defined at the previous step.

The method of the invention is for evaluating “the effects of a multiconductor interconnection on one or more electrical variables in a circuit”. This must be interpreted in a broad sense, as: the effects of a multiconductor interconnection on one or more electrical variables in any type of electrical or electronic circuit or system.

The multiconductor transmission line model is not capable of describing all interconnections structures, but it must be suitable for modeling the segment of the multiconductor interconnection, in the known frequency band, with a sufficient accuracy. For instance, an electrically short length of the multiconductor interconnection may comprise vias on one or more transmission conductors, or stubs for the connection of devices to the multiconductor interconnections. Such an electrically short length of a multiconductor interconnection is often modeled with a lumped-element section, made of an RLC network. However, according to the invention, at least one part of the multiconductor interconnection, referred to as “the segment” is modeled as a multiconductor transmission line.

The skin effect and the proximity effect are well known to specialists. Here, “skin effect” refers to the normal skin effect or to the anomalous skin effect. The difference between the normal skin effect and the anomalous skin effect is for instance explained in the Chapter 4 of the book of R. E. Matik entitled “Transmission lines for digital and communication networks”, published by the IEEE Press in 1995. The specialist understands the wordings “at frequencies for which the skin effect is fully developed” and “at frequencies for which the skin effect is negligible”.

The method of the invention may for instance be such that said power is equal to 1/2, so that, in this case, said “ratio of the function to an exponentiation involving frequency” is equal to the ratio of the function to the square root of the frequency. This approach is preferred when the known frequency band is below 100 GHz. However, the anomalous skin effect may play a significant role, for instance when the known frequency band contains frequencies above 100 GHz. In this case, the method of the invention may for instance be such that said power is equal to 2/3, so that, in this case, said “ratio of the function to an exponentiation involving frequency” is equal to the ratio of the function to the cube root of the frequency squared.

The invention is also about a computer program product for implementing the method of the invention. The computer program product of the invention is a computer program product for evaluating, in a known frequency band, the effects of a multiconductor interconnection on one or more electrical variables in a circuit, the multiconductor interconnection being a part of the circuit, the multiconductor interconnection having n transmission conductors, where n is an integer greater than or equal to two, the computer program product comprising a storage medium containing the instructions of a computer program, the computer program product being characterized in that:
a computer running the computer program computes, at one or more given frequencies, for a segment of the interconnection, a parameter representative of a non-diagonal entry of the per-unit-length internal impedance matrix of the segment, the parameter being given by a function of frequency, of one or more frequency independent quantities representative of the resistive losses in the conductors of the segment at frequencies for which the skin effect is fully developed, and of one or more frequency independent quantities representative of the resistive losses in the conductors of the segment at frequencies for which the skin effect is negligible, the function being defined at any nonnegative frequency, the limit, as the frequency becomes arbitrarily large, of the ratio of the function to an exponentiation involving frequency existing and being a nonzero complex number, the exponentiation involving frequency being equal to frequency raised to a power, said power being greater than or equal to 1/4 and less than or equal to 4/5, the function being differentiable with respect to frequency at any nonnegative frequency and the partial derivative of the function with respect to frequency at the frequency of zero Hertz being a number having an imaginary part greater than the absolute value of its real part;
a computer running the computer program simulates the circuit using, at said one or more given frequencies, said parameter representative of a non-diagonal entry of the per-unit-length internal impedance matrix of the segment.

The computer program product of the invention may for instance be such that said power is equal to 1/2. This approach is preferred, as explained above. The computer program product of the invention may for instance be such that said power is equal to 2/3.

### BRIEF DESCRIPTION OF THE DRAWINGS

Other advantages and characteristics will appear more clearly from the following description of particular embodiments of the invention, given by way of non-limiting examples, with reference to the accompanying drawings in which:

FIG. 1 depicts a flow chart of a first embodiment of the method of the invention;

FIG. 2 depicts a flow chart of a second embodiment of the method of the invention.

### DETAILED DESCRIPTION OF SOME EMBODIMENTS

### First Embodiment

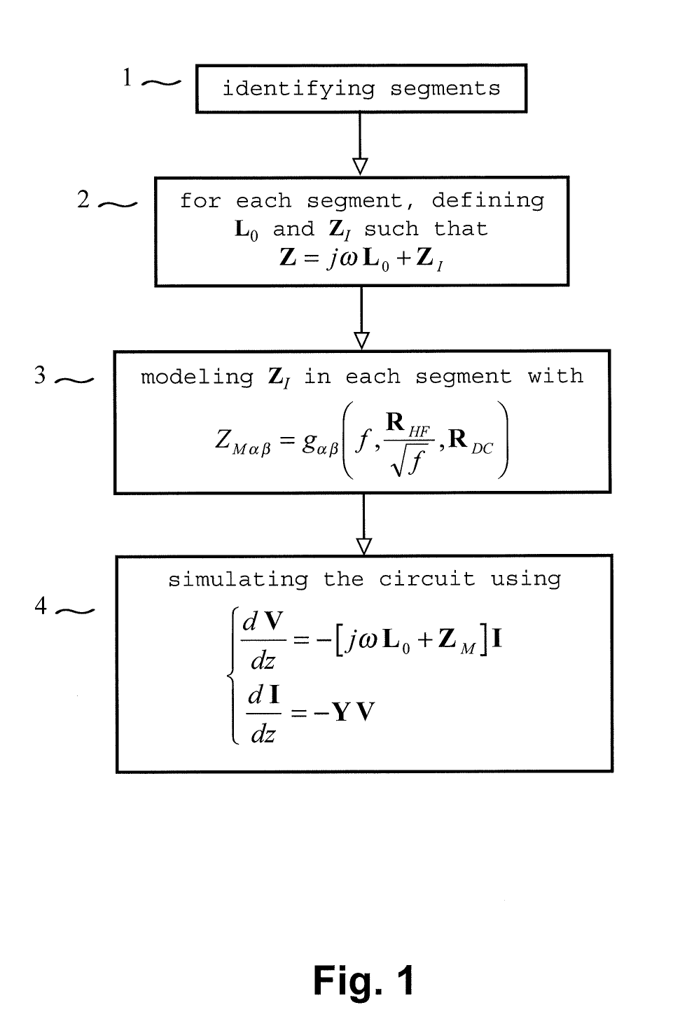

As a first embodiment of the method of the invention, given by way of non-limiting example, we have represented in FIG. 1 a flow chart of a method for evaluating, in a known frequency band, the effects of a multiconductor interconnection on one or more electrical variables in a circuit, the multiconductor interconnection being a part of the circuit, the multiconductor interconnection having n transmission conductors and a reference conductor, where n is an integer greater than or equal to two, the method comprising the steps of:
identifying (1) one or more segments of the multiconductor interconnection, each of the segments being such that, over said each of the segments, the multiconductor interconnection is modeled, in the known frequency band, as a multiconductor transmission line having a per-unit-length impedance matrix, said per-unit-length impedance matrix being referred to as the total per-unit-length impedance matrix of the segment, the total per-unit-length impedance matrix of the segment being an n×n matrix denoted by Z;
defining (2), for each of the segments, a per-unit-length external inductance matrix of the segment and a per-unit-length internal impedance matrix of the segment, the per-unit-length external inductance matrix of the segment being a real n×n matrix denoted by L₀ and defined as the per-unit-length inductance matrix of the segment computed using the current distribution in the conductors of the segment at frequencies for which the skin effect and the proximity effect are fully developed, the per-unit-length internal impedance matrix of the segment being a complex n×n matrix denoted by Z_{I} and given by

Z=Z_{I}+jωL₀

where ω is the radian frequency, Z_{I} being a non-diagonal matrix in a part of the known frequency band;
defining (3), for each of the segments, a model, denoted by Z_{M}, of the per-unit-length internal impedance matrix of the segment, Z_{M} being a complex n×n matrix such that any entry Z_{M α β} of Z_{M} is given by a function of frequency, of one or more frequency independent quantities representative of the resistive losses in the conductors of the segment at frequencies for which the skin effect and the proximity effect are fully developed, and of one or more frequency independent quantities representative of the resistive losses in the conductors of the segment at frequencies for which the skin effect and the proximity effect are negligible;
simulating (4) the circuit using, in the known frequency band, for each of the segments, a multiconductor transmission line model and the model of the per-unit-length internal impedance matrix of the segment defined at the previous step, so that the telegrapher's equations applicable to the segment are:

$$\{ \begin{matrix}\frac{d V}{d z} = - [ jω {L}_{0} + {Z}_{M} ] I \\ \frac{d I}{d z} = - YV\end{matrix}$$

where V is the column-vector of the voltages between the transmission conductors and the reference conductor, I is the column-vector of the currents in the transmission conductors, L₀ is the per-unit-length external inductance matrix of the segment, Z_{M} is the model of the per-unit-length internal impedance matrix of the segment defined at the previous step, Y is the per-unit-length admittance matrix of the segment, and z is the abscissa along the segment.

A specialist knows that, at frequencies for which the skin effect and the proximity effect are fully developed, the per-unit-length resistance matrix of any one of the segments is proportional to the square root of the frequency, in the case of the normal skin effect. Consequently, for each of the segments, the product of the inverse of the square root of the frequency and the per-unit-length resistance matrix of the segment at a frequency for which the skin effect and the proximity effect are fully developed is a frequency independent quantity representative of the resistive losses in the conductors of the segment at frequencies for which the skin effect and the proximity effect are fully developed. Moreover, for each of the segments, the per-unit-length resistance matrix of the segment at the frequency of zero Hertz (that is to say, the dc per-unit-length resistance matrix of the segment) is a frequency independent quantity representative of the resistive losses in the conductors of the segment at frequencies for which the skin effect and the proximity effect are negligible. In this first embodiment, for each of the segments, any entry Z_{M α β} of Z_{M} is given by:

$${Z}_{M αβ} = {g}_{αβ} ( f , \frac{{R}_{HF}}{\sqrt{f}} , {R}_{DC} )$$

where α and β are integers greater than or equal to 1 and less than or equal to n, f is the frequency, R_{HF} is the per-unit-length resistance matrix of the segment at frequencies for which the skin effect and the proximity effect are fully developed, R_{DC} is the per-unit-length resistance matrix of the segment at the frequency of zero Hertz, and g_{α β} is a function of f, of f^{-1/2} R_{HF} and of R_{DC}. Each function g_{α β} is defined at any nonnegative frequency. At the frequency of zero Hertz, each function g_{α β} is equal to R_{DC α β}, where R_{DC α β} denotes an entry of R_{DC}. The limit, as the frequency becomes arbitrarily large, of each g_{α β}/f^{1/2} exists and is a nonzero complex number equal to (1+j)f^{-1/2} R_{HF α β}, where R_{HF α β} denotes an entry of R_{HF}. Each function g_{α β} is differentiable with respect to frequency at any nonnegative frequency and the partial derivative of each function g_{α β} with respect to frequency at the frequency of zero Hertz is an imaginary number having a positive imaginary part. Using these properties of the functions g_{α β}, it can be shown that Z_{M} is a good approximation of Z_{I} at any frequency.

The specialist understands that a computer program product of the invention implementing the method of this first embodiment is preferably such that:
a computer running the computer program computes, for each of the segments, the frequency independent matrices L₀, f^{-1/2} R_{HF} and R_{DC};
a computer running the computer program computes, at one or more given frequencies, for each of the segments, each entry of Z_{M} using the formula given above for Z_{M α β} and the fact that Z_{M} is a symmetric matrix;
a computer running the computer program simulates the circuit using, at said one or more given frequencies, for each of the segments, the above defined telegrapher's equations applicable to the segment and containing Z_{M}.

We note that, in some cases, some of the entries of Z_{M} may be negligible, for instance a non-diagonal entry corresponding to two transmission conductors physically very far from each other. Such entries will have a very small absolute value, compared to the largest absolute value of the non-diagonal entries of Z_{M}. The specialist understands that, in order to reduce the computation time, it is possible to set the values of such entries of Z_{M} to zero, so that it is no longer necessary to compute them. In this case:
the method of the invention is such that only the non-negligible entries of Z_{M} are given by a function of frequency, of one or more frequency independent quantities representative of the resistive losses in the conductors of the segment at frequencies for which the skin effect and the proximity effect are fully developed, and of one or more frequency independent quantities representative of the resistive losses in the conductors of the segment at frequencies for which the skin effect and the proximity effect are negligible;
at one or more given frequencies, for each of the segments, a computer running the computer program sets each negligible entry of Z_{M} to zero, and computes each non negligible entry of Z_{M} using the formula given above for Z_{M α β} and the fact that Z_{M} is a symmetric matrix.

### Second Embodiment (Best Mode)

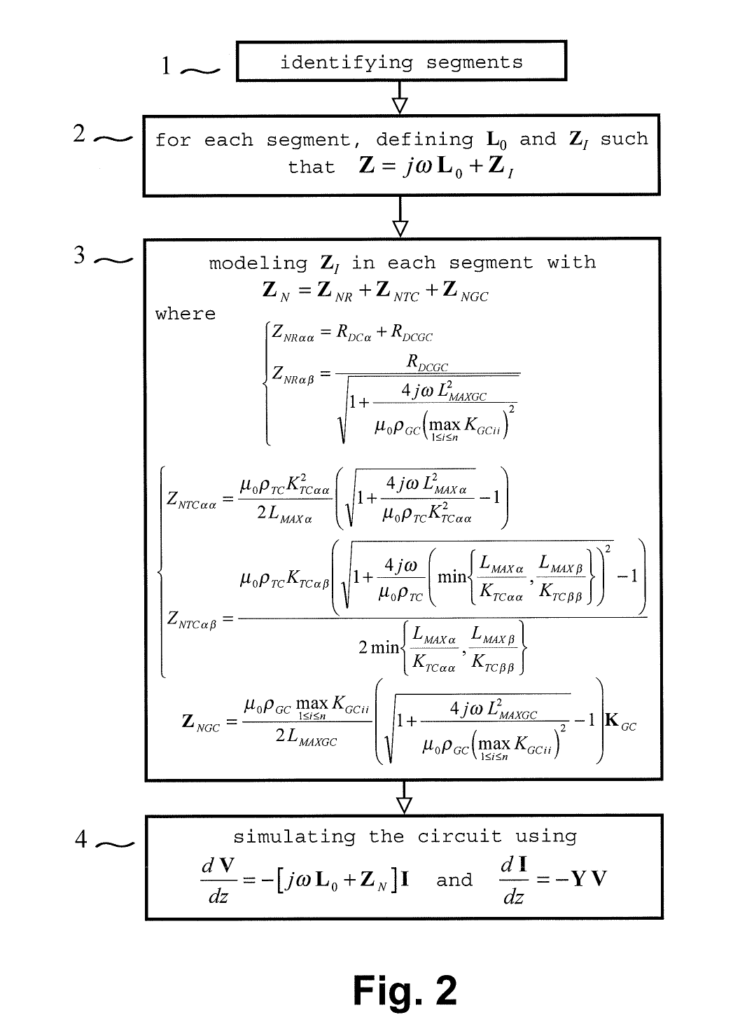

As a second embodiment of the method of the invention, given by way of non-limiting example and best mode of carrying out the invention, we have represented in FIG. 2 a flow chart of a method for evaluating, in a known frequency band, the effects of a multiconductor interconnection on one or more electrical variables in a circuit, the multiconductor interconnection being a part of the circuit, the multiconductor interconnection having n transmission conductors and a reference conductor, where n is an integer greater than or equal to three, the method comprising the steps of:
identifying (1) one or more segments of the multiconductor interconnection, each of the segments being such that, over said each of the segments, the multiconductor interconnection is modeled, in the known frequency band, as a uniform multiconductor transmission line having a per-unit-length impedance matrix, said per-unit-length impedance matrix being referred to as the total per-unit-length impedance matrix of the segment, the total per-unit-length impedance matrix of the segment being a complex n×n matrix denoted by Z;
defining (2), for each of the segments, a per-unit-length external inductance matrix of the segment, denoted by L₀, and a per-unit-length internal impedance matrix of the segment, denoted by Z_{I}, as in the first embodiment;
defining (3), for each of the segments, a model, denoted by Z_{N}, of the per-unit-length internal impedance matrix of the segment, Z_{N} being a complex n×n matrix such that any entry Z_{N α β} of Z_{N} is given by a function of frequency, of one or more frequency independent quantities representative of the resistive losses in the conductors of the segment at frequencies for which the skin effect and the proximity effect are fully developed, and of one or more frequency independent quantities representative of the resistive losses in the conductors of the segment at frequencies for which the skin effect and the proximity effect are negligible;
simulating (4) the circuit using, in the known frequency band, for each of the segments, a multiconductor transmission line model and the model of the per-unit-length internal impedance matrix of the segment defined at the previous step, so that the telegrapher's equations applicable to the segment are:

$$\{ \begin{matrix}\frac{d V}{d z} = - [ jω {L}_{0} + {Z}_{N} ] I \\ \frac{d I}{d z} = - YV\end{matrix}$$

where V is the column-vector of the voltages between the transmission conductors and the reference conductor, I is the column-vector of the currents in the transmission conductors, L₀ is the per-unit-length external inductance matrix of the segment, Z_{N} is the model of the per-unit-length internal impedance matrix of the segment defined at the previous step, Y is the per-unit-length admittance matrix of the segment, and z is the abscissa along the segment.

In this second embodiment, for each of the segments, Z_{N} is defined by

Z_{N}=Z_{NR}+Z_{NTC}+Z_{NGC}

where the matrices Z_{NR}, Z_{NTC} and Z_{NGC} are defined below using two frequency-independent matrices introduced in the article of F. Broyde and E. Clavelier entitled “A simple computation of the high-frequency per-unit-length resistance matrix”, published in the proceedings of the 2011 IEEE 15th Workshop on Signal Propagation on Interconnects, SPI 2011, which took place in May 2011:
the matrix of the equivalent inverse widths of the transmission conductors, denoted by K_{TC};
the matrix of the equivalent inverse widths of the reference conductor, denoted by K_{GC}.

We shall use K_{TC α β} to denote an entry of K_{TC} and K_{GC α β} to denote an entry of K_{GC}.

For indices α and β ranging from 1 to n with α≠β, the entries Z_{NR α α} and Z_{NR α β} of the matrix Z_{NR} are given by

$$\{ \begin{matrix}{Z}_{NR αα} = {R}_{DC α} + {R}_{DCGC} \\ {Z}_{NR αβ} = \frac{{R}_{DCGC}}{\sqrt{1 + \frac{4 jω {L}_{MAXGC}^{2}}{{μ}_{0} {{ρ}_{GC} ( {max}_{1 \leq i \leq n} {K}_{GCii} )}^{2}}}}\end{matrix}$$

where the square root symbol denotes the principal root, where the dc per-unit-length resistances of the transmission conductors are denoted by R_{DC 1} to R_{DC n}, where the dc per-unit-length resistance of the reference conductors is denoted by R_{DCGC}, where the per-unit-length inductance L_{MAXGC} relates to the reference conductor, where μ₀ is the permeability of vacuum, where ρ_{GC} is the resistivity of the reference conductor and where “max” designates the greatest element.

For indices α and β ranging from 1 to n with α≠β, the entries Z_{NTC α α} and Z_{NTC α β} of the matrix Z_{NTC} are given by

$$\{ \begin{matrix}{Z}_{NTC αα} = \frac{{μ}_{0} {ρ}_{TC} {K}_{TC αα}^{2}}{2 {L}_{MAX α}} ( \sqrt{1 + \frac{4 jω {L}_{MAX α}^{2}}{{μ}_{0} {ρ}_{TC} {K}_{TC αα}^{2}} - 1} ) \\ {Z}_{NTC αβ} = \frac{{μ}_{0} {ρ}_{TC} {K}_{TC αβ} ( \sqrt{1 + \frac{4 jω}{{μ}_{0} {ρ}_{TC}} {( min \{ \frac{{L}_{MAX α}}{{K}_{TC αα}} , \frac{{L}_{MAX β}}{{K}_{TC ββ}} \} )}^{2}} - 1 )}{2 min \{ \frac{{L}_{MAX α}}{{K}_{TC αα}} , \frac{{L}_{MAX β}}{{K}_{TC ββ}} \}}\end{matrix}$$

where each square root symbol denotes the principal root, where the per-unit-length inductances L_{MAX 1} to L_{MAX n} relate to the transmission conductors, where ρ_{TC} is the resistivity of the transmission conductors and where “min” designates the smallest element.

The matrix Z_{NGC} is given by

$${Z}_{NGC} = \frac{{μ}_{0} {ρ}_{GC} {max}_{1 \leq i \leq n} {K}_{GCii}}{2 {L}_{MAXGC}} ( \sqrt{1 + \frac{4 jω {L}_{MAXGC}^{2}}{{μ}_{0} {{ρ}_{GC} ( {max}_{1 \leq i \leq n} {K}_{GCii} )}^{2}} - 1} ) {K}_{GC}$$

where the square root symbol denotes the principal root.

We note that, in this second embodiment, the method of the invention is such that the same analytical expression is used for computing a plurality of diagonal entries of the model of the per-unit-length internal impedance matrix of any one of the segments, and such that the same analytical expression is used for computing a plurality of non-diagonal entries of the model of the per-unit-length internal impedance matrix of any one of the segments.

Taking into account the properties of K_{TC} and K_{GC}, it can be shown that, for each entry Z_{N α β} of Z_{N}, the limit, as the frequency becomes arbitrarily large, of Z_{N α β}/f^{1/2} exists and is a nonzero complex number; that Z_{N α β} is differentiable with respect to frequency at any nonnegative frequency; and that the partial derivative of Z_{N α β} with respect to frequency at the frequency of zero Hertz is an imaginary number having a positive imaginary part. It can be shown that the analytical model Z_{N} is a very good approximation of Z_{I} at any frequency, because it is exact at dc, it is accurate at high frequencies, it produces finite dc self-inductances and mutual inductances, and it represents a causal and passive linear system.

The specialist understands that a computer program product of the invention implementing the method of this second embodiment is preferably such that:
a computer running the computer program computes, for each of the segments, the frequency independent matrices L₀, K_{TC} and K_{GC};
a computer running the computer program computes, at one or more given frequencies, for each of the segments, Z_{N} using the formulas given above and the fact that Z_{N} is a symmetric matrix;
a computer running the computer program simulates the circuit using, at said one or more given frequencies, for each of the segments, the above defined telegrapher's equations applicable to the segment and containing Z_{N}.

The specialist understands that the simulation of a non-uniform multiconductor transmission line is more complex than the simulation of a uniform multiconductor transmission line. Thus, in this second embodiment, the circuit simulation step is simplified by the fact that, over each of the segments, the multiconductor interconnection is modeled, in the known frequency band, as a uniform multiconductor transmission line.

### INDICATIONS ON INDUSTRIAL APPLICATIONS

The method of the invention is suitable for reducing the computation time for the simulation of an electronic circuit or system, for instance when the simulation must accurately predict propagation delays, attenuation, linear distortions caused by the variations of attenuation and propagation velocity with frequency, couplings between conductors and reflections. The method of the invention has the advantage of being able to use the length of an interconnection as a parameter of an accurate simulation, and of being such that a change in the length of the interconnection does not require a long computation time to obtain new simulation results. Consequently, the method of the invention can be used for improving the characteristics and reduce the cost of electronic circuits implemented in printed circuit assemblies, multi-chip modules (MCMs) and integrated circuits.

The method of the invention is also suitable for reducing the computation time for the simulation of transient phenomena in electrical power networks, for instance when the simulation must accurately predict transient waveforms and take into account the variations of attenuation and propagation velocity with frequency, the couplings between conductors and reflections. Consequently, the method of the invention can for instance be used for improving the efficiency and reduce the cost of protective measures for protecting an electrical power network from transient overvoltages.

1. A method for evaluating, in a known frequency band, the effects of a multiconductor interconnection on one or more electrical variables in a circuit, the multiconductor interconnection being a part of the circuit, the multiconductor interconnection having n transmission conductors, where n is an integer greater than or equal to two, the method comprising the steps of:
identifying a segment of the multiconductor interconnection, the segment being such that, over the segment, the multiconductor interconnection may be modeled, in the known frequency band, as a multiconductor transmission line having a per-unit-length impedance matrix, said per-unit-length impedance matrix being referred to as the total per-unit-length impedance matrix of the segment;
defining a per-unit-length external impedance matrix of the segment as the per-unit-length impedance matrix of the segment if all conductors of the segment were ideal conductors, and a per-unit-length internal impedance matrix of the segment as the total per-unit-length impedance matrix of the segment minus the per-unit-length external impedance matrix of the segment, the per-unit-length internal impedance matrix of the segment being a non-diagonal matrix in a part of the known frequency band;
defining a model of the per-unit-length internal impedance matrix of the segment, the model of the per-unit-length internal impedance matrix of the segment being a complex n×n matrix such that a non-diagonal entry of the model of the per-unit-length internal impedance matrix of the segment is given by a function of frequency, of one or more frequency independent quantities representative of the resistive losses in the conductors of the segment at frequencies for which the skin effect is fully developed, and of one or more frequency independent quantities representative of the resistive losses in the conductors of the segment at frequencies for which the skin effect is negligible, the function being defined at any nonnegative frequency, the limit, as the frequency becomes arbitrarily large, of the ratio of the function to an exponentiation involving frequency existing and being a nonzero complex number, the exponentiation involving frequency being equal to frequency raised to a power, said power being greater than or equal to 1/4 and less than or equal to 4/5, the function being differentiable with respect to frequency at any nonnegative frequency and the partial derivative of the function with respect to frequency at the frequency of zero Hertz being a number having an imaginary part greater than the absolute value of its real part;
simulating the circuit using, in the known frequency band, for the segment, a multiconductor transmission line model and the model of the per-unit-length internal impedance matrix of the segment defined at the previous step.

2. The method of claim 1, wherein said power is equal to 1/2.

3. The method of claim 1, wherein the partial derivative of the function with respect to frequency at the frequency of zero Hertz is an imaginary number.

4. The method of claim 1, wherein, over the segment, the multiconductor interconnection is modeled, in the known frequency band, as a uniform multiconductor transmission line.

5. The method of claim 1, wherein the same analytical expression is used for computing a plurality of diagonal entries of the model of the per-unit-length internal impedance matrix of the segment.

6. The method of claim 1, wherein the same analytical expression is used for computing a plurality of non-diagonal entries of the model of the per-unit-length internal impedance matrix of the segment.

7. A computer program product for evaluating, in a known frequency band, the effects of a multiconductor interconnection on one or more electrical variables in a circuit, the multiconductor interconnection being a part of the circuit, the multiconductor interconnection having n transmission conductors, where n is an integer greater than or equal to two, the computer program product comprising a storage medium containing the instructions of a computer program, the computer program product being characterized in that:
a computer running the computer program computes, at one or more given frequencies, for a segment of the interconnection, a parameter representative of a non-diagonal entry of a per-unit-length internal impedance matrix of the segment, the parameter being given by a function of frequency, of one or more frequency independent quantities representative of the resistive losses in the conductors of the segment at frequencies for which the skin effect is fully developed, and of one or more frequency independent quantities representative of the resistive losses in the conductors of the segment at frequencies for which the skin effect is negligible, the function being defined at any nonnegative frequency, the limit, as the frequency becomes arbitrarily large, of the ratio of the function to an exponentiation involving frequency existing and being a nonzero complex number, the exponentiation involving frequency being equal to frequency raised to a power, said power being greater than or equal to 1/4 and less than or equal to 4/5, the function being differentiable with respect to frequency at any nonnegative frequency and the partial derivative of the function with respect to frequency at the frequency of zero Hertz being a number having an imaginary part greater than the absolute value of its real part;
a computer running the computer program simulates the circuit using, at said one or more given frequencies, said parameter representative of a non-diagonal entry of the per-unit-length internal impedance matrix of the segment.

8. The computer program product of claim 7, wherein said power is equal to 1/2.

9. The computer program product of claim 7, wherein the partial derivative of the function with respect to frequency at the frequency of zero Hertz is an imaginary number.
